(19) United States
(12) Patent Application Publication
(10) Pub. No.: US 2007/0090856 A1
(43) Pub. Date: Apr. 26, 2007

(54) Non-contact detecting device for a panel

(75) Inventors: Kuo-Ting Liao, Kuei Shan Hsiang (TW); Chih-Chiang Chen, Kuei Shan Hsiang (TW); Kuo-Kuei Lee, Kuei Shan Hsiang (TW); Yi-Te Huang, Kuei Shan Hsiang (TW)

Correspondence Address: BACON & THOMAS, PLLC, 625 SLATERS LANE, FOURTH FLOOR, ALEXANDRIA, VA, 22314, US

(73) Assignee: Quanta Display Inc., Kuei Shan Hsiang (TW)

(21) Appl. No.: 11/407,942

(22) Filed: Apr. 21, 2006

(30) Foreign Application Priority Data
Oct. 26, 2005 (TW) 094137477

(51) Int. Cl. G01R 31/00

(52) U.S. Cl. 324/770

(57) ABSTRACT

A non-contact inspecting device for a panel, which has a plurality of signal inputting sensors, a plurality of signal detecting sensors and a control circuit. The signal inputting sensors are configured in a first detecting bar, and the signal detecting sensors are configured in a second detecting bar. When the device inspects the panel, the control circuit controls the signal input sensors of the first detecting bar to provide a detecting signal and controls the corresponding signal detecting sensors of the second detecting bar to receive the detecting signal synchronously, thereby relatively reducing tact-time.

### BACKGROUND OF THE INVENTION

1. Field of the Invention

The invention relates to a non-contact inspecting device for a panel and, more particularly, to a non-contact inspecting device suitable for inspecting gate and source lines of an active matrix substrate, like thin-film transistor array (TFT-array) substrate, or inspecting column lines and row lines of a passive matrix substrate.

2. Description of Related Art

FIG. 1 shows a schematic diagram of a panel 1 of a flat panel display. As shown in FIG. 1, there are a plurality of row lines (horizontal lines) 110 and a plurality of column lines (vertical lines) 120 on the panel 1. The row lines 110 are referred to as gate lines; the column lines 120 are referred to as source lines. In the manufacturing process for the panel 1, the horizontal or column lines 110 or 120 on the panel 1 may be open or short-circuited. Accordingly, inspection is typically applied to the gate and source lines.

Current inspection for panels of flat panel displays is divided essentially into two types: contact and non-contact inspection.

FIG. 2 shows a schematic diagram of a typical contact inspection. As shown in FIG. 2, the typical contact inspection uses a probe card 21 to inspect a panel 22. The probe card 21 is provided with a plurality of probes 2111-2116 at a constant number. When the row lines 221-223 of the panel 21 are inspected, the probes 2111-2116 of the probe card 21 are aligned at two sides of the row lines 221-223 respectively. Namely, the probes 2111 and 2112 are aligned at the two sides of the row line 221, the probes 2113 and 2114 are aligned at the two sides of the row line 222, and the probes 2115 and 2116 are aligned at the two sides of the row line 223. Next, the probes 2111-2116 of the probe card 21 are in contact with the row lines 221-223 respectively. Next, the probe card 21 provides a potential difference to the two sides of the row lines 221-223 respectively and accordingly measures respective resistance of the row lines 221-223. When one of the row lines such as 222 has a measured resistance over a predetermined range for the gate lines, it means the row line 222 is possibly open. Alternatively, when a row line such as 223 has a measured resistance close to zero, it means the row line 223 is possibly short-circuited.

However, the cited inspection consumes too much time. For example, if the probe card 21 has one side of 384 probes and a panel to be inspected has a resolution of 768×1024 (768 row lines×1024×RGB column lines), the probes have to align and contact the row lines on the panel, and the probe card is removed from the panel after the inspection is complete. In addition, because the quantity of probes (384) is half the quantity of row lines (768), the probe card has to inspect the panel twice in order to complete a row line inspection. Namely, the probe card has to perform the cited steps (alignment, contact, inspection and removal) again to thus complete the row line inspection, which consumes too much time.

Further, the quantity of probes is fixed, but the panels can have various resolutions. In this case, various probe cards are used in the panels for inspecting the various resolutions, and thus the production cost is increased. For example, for the probe card 21 with one side of 384 probes cited above, if panels to be inspected possibly have a respective resolution of 768×1024 (768 row lines×1024×RGB column lines), 1088×612 or 1280×1024, appropriate probe cards are prepared to inspect the resolutions of the panels.

FIGS. 3a and 3b show schematic diagrams of a conventional non-contact inspecting device 30. As shown in FIG. 3a, the conventional non-contact inspecting device 30 (FIG. 3b) has an inputting sensor 31 and a receiving sensor 32 to inspect a row line 33 of a panel 3 (FIG. 3b). The inputting sensor 31 provides a high voltage to the row line 33 so as to produce induced charges in the row line 33. The receiving sensor 32 receives the induced charges and accordingly determines whether the row line 33 has a defect or not.

FIG. 3b shows a schematic diagram of the conventional non-contact inspecting device 30 inspecting the panel 3. As shown in FIG. 3b, two sides of the device 30 are configured with the inputting sensor 31 and the receiving sensor 32 respectively. The device 30 uses the induced charges to inspect the panel 3, and accordingly a gap between a probe of the non-contact inspecting device 30 and the panel 3 is limited to a very small value, such as 100 mm. In addition, the device 30 can detect only one row line or one column line at a time. At this point, the device 30 has to inspect the panel 3 in a scan manner from top to bottom, for example. However, since the gap between the probe of the non-contact inspecting device 30 and the panel 3 is very small, in the case of the panel 3 having particles, the device 30 can easily scrape the panel 3 in movement and scanning.

Therefore, it is desirable to provide an improved method to mitigate and/or obviate the aforementioned problems.

### SUMMARY OF THE INVENTION

An object of the invention is to provide a non-contact inspecting device for a panel, which can reduce the tact-time and effectively increase the panel productivity.

Another object of the invention is to provide a non-contact inspecting device for a panel, which can relatively reduce the cost of inspecting equipment.

Yet another object of the invention is to provide a non-contact inspecting device for a panel, which can reduce the panel-scraping probability occurring in inspection.

An aspect of this invention is to provide a non-contact inspecting device for a panel, which is applied to inspect the panel with a plurality of conducting lines. The conducting lines includes metal and its related alloy, transparent conductive oxide (TCO), or conductive organic polymer. The non-contact inspecting device includes a first detecting bar, a second detecting bar and a control circuit. The first detecting bar is configured with a plurality of signal inputting sensors, and the second detecting bar is configured with a plurality of signal detecting sensors, wherein the signal inputting sensors and the signal detecting sensors are combined to form a plurality of detecting units. The control circuit is electrically connected to the signal inputting sensors and the signal detecting sensors respectively. When the non-contact inspecting device inspects the panel, each of the detecting units corresponds to a conducting line such that the control circuit controls the detecting unit to inspect the conducting line.

Another aspect of this invention is to provide a non-contact inspecting device for a panel, which is applied to inspect the panel with a plurality of conducting lines. The conducting lines includes metal and its related alloy, transparent conductive oxide (TCO), or conductive organic polymer. The non-contact inspecting device includes a first detecting bar, a signal detecting sensor and a control circuit. The first detecting bar is configured with a plurality of signal inputting sensors. One of the signal inputting sensors and the signal detecting sensor form a detecting unit. The control circuit is electrically connected to the signal inputting sensors and the signal detecting sensor respectively. When the non-contact inspecting device inspects the panel, the detecting unit corresponds to a conducting line such that the control circuit controls the detecting unit to detect the conducting line. For a subsequent conducting line to be detected by the detecting unit, the signal detecting sensor is mechanically moved to align with another signal input sensor relative to the subsequent conducting line for detection.

Another aspect of this invention is to provide a non-contact inspecting device for a panel, which is applied to inspect the panel with a plurality of conducting lines. The conducting lines includes metal and its related alloy, transparent conductive oxide (TCO), or conductive organic polymer. The non-contact inspecting device includes a signal inputting sensor, a second detecting bar and a control circuit. The second detecting bar is configured with a plurality of signal detecting sensors. The signal inputting sensor and one or more signal detecting sensors form a detecting unit. The control circuit is electrically connected to the signal inputting sensor and the signal detecting sensors respectively. When the non-contact inspecting device inspects the panel, each of the detecting units of the panel corresponds to a conducting line such that the control circuit controls the detecting unit to detect the conducting line. For a subsequent conducting line to be detected by the detecting unit, the signal inputting sensor is mechanically moved to corresponding one or more signal detecting sensors relative to the subsequent conducting line for detection.

In addition to controlling the detecting unit to detect the conducting line, the control circuit controls one of the signal input sensor of the first detecting bar to provide a detecting signal and controls the corresponding signal detecting sensor of the second detecting bar to detect the detecting signal synchronously. In another embodiment, the control circuit can control a plurality of detecting units to detect the corresponding conducting lines.

In addition, the control circuit controls one of the signal input sensors of the first detecting bar to provide a voltage such that the conducting lines produce induced charges and control one of the signal detecting sensors of the second detecting bar to detect the conducting lines by receiving the induced charges.

The control circuit sequentially controls the detecting units to detect the conducting lines, which achieves the inspection of the conducting lines in an electronic scanning manner, thereby speeding the tact-time and avoiding a panel scrape.

The detecting unit includes one signal inputting sensor and one signal detecting sensor, or one signal inputting sensor and a plurality of signal detecting sensors.

The panel to be inspected is a raw thin-film transistor array (TFT-array) substrate or passive matrix substrate, or a sliced TFT-array substrate or passive matrix substrate.

Other objects, advantages, and novel features of the invention will become more apparent from the following detailed description when taken in conjunction with the accompanying drawings.

### BRIEF DESCRIPTION OF THE DRAWINGS

FIG. 1 is a schematic diagram of a typical panel of a flat panel display;

FIG. 2 is a schematic diagram of a typical contact inspection;

FIG. 3a is a schematic diagram of a typical non-contact inspection;

FIG. 3b is a schematic diagram of using a typical non-contact inspecting device to inspect a panel;

FIG. 4 is a block diagram of a non-contact inspecting device for a panel according to an embodiment of the invention;

FIG. 5 is a schematic diagram of using a non-contact inspecting device to inspect the panel according to an embodiment of the invention;

FIGS. 6a and 6b are schematic diagrams of a second embodiment of the invention;

FIG. 7 is a schematic diagram of a third embodiment of the invention; and

FIG. 8 is a schematic diagram of a fourth embodiment of the invention.

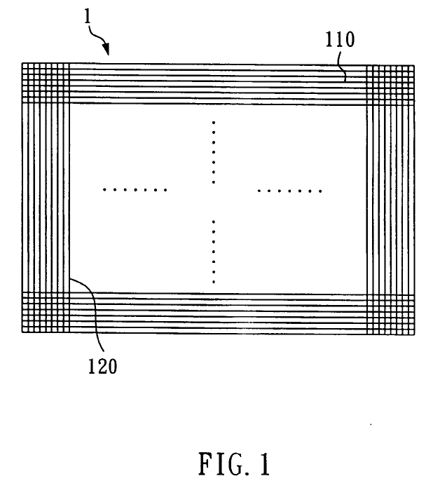

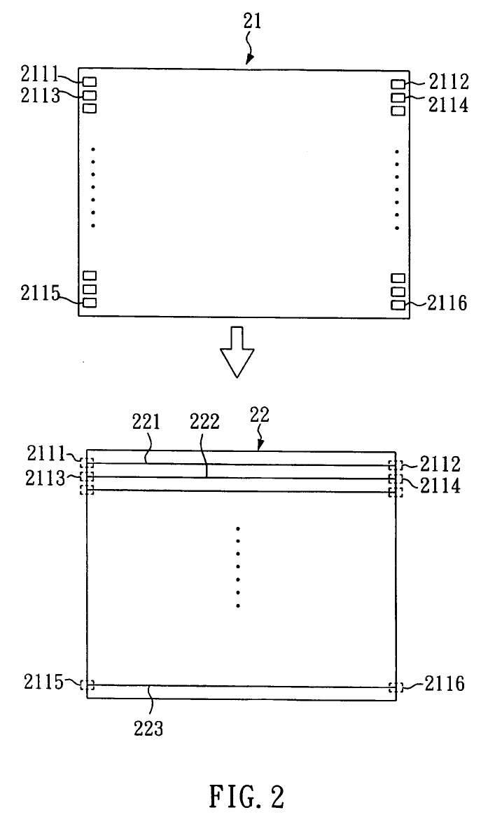

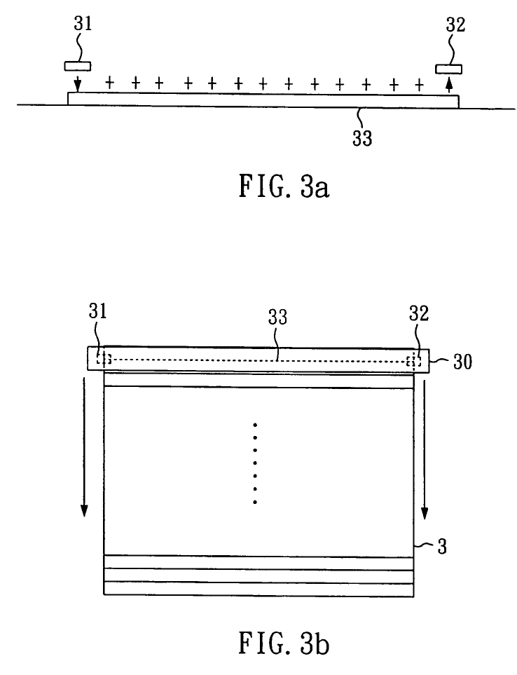

### DETAILED DESCRIPTION OF THE PREFERRED EMBODIMENT

A non-contact inspecting device for a panel is provided, which configures a plurality of signal inputting sensors in a first detecting bar and a plurality of signal detecting sensors in a second detecting bar. Accordingly, the conducting lines on the panel can be inspected directly through the first and the second detecting bars in such a way that each signal inputting sensor of the first detecting bar is aligned to one end of a respective conducting line to be detected and each signal detecting sensor of the second detecting bar is also aligned to the other end of the respective conducting line to be detected. Thus, when the non-contact inspecting device inspects the panel, the inspection can be quickly completed by electronically controlling the signal inputting sensors to provide a detecting signal and also controlling the signal detecting sensors of the second detecting bar to receive the detecting signal synchronously, thereby relatively reducing the tact-time.

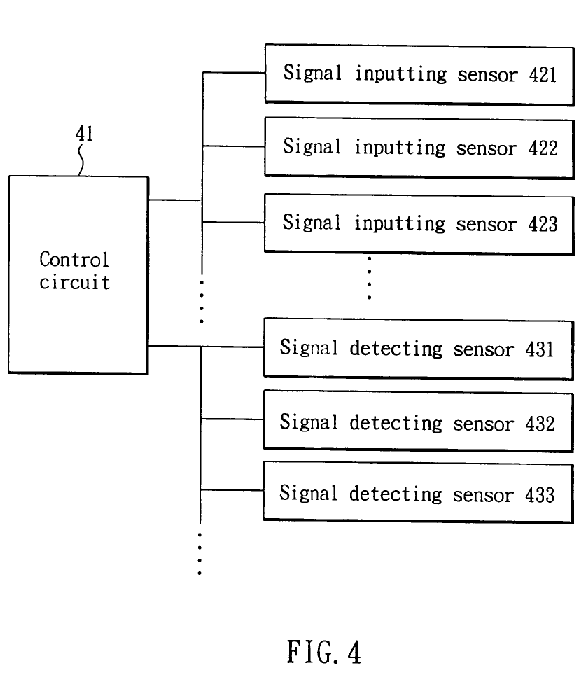

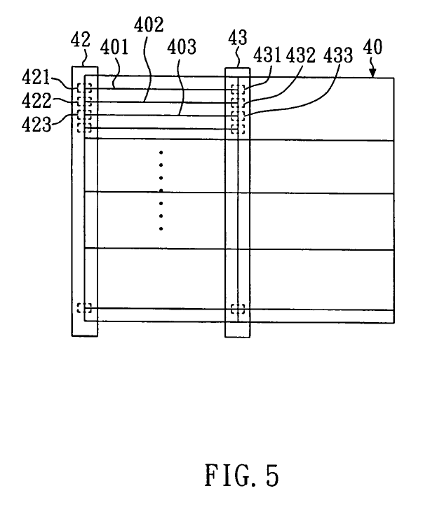

Please refer to FIG. 4 and FIG. 5, which depict the first preferred embodiment of the present invention. FIG. 4 is a block diagram of a non-contact inspecting device. FIG. 5 is a schematic diagram of using the non-contact inspecting device of FIG. 4 to inspect the panel 40. In FIG. 4, the non-contact inspecting device includes a control circuit 41, a plurality of signal inputting sensors 421, 422, 423 and a plurality of signal inspecting sensors 431, 432, 433.

The control circuit 41 is electrically connected to the signal inputting sensors 421, 422, 423 and the signal inspecting sensors 431, 432, 433, respectively.

In FIG. 5, an example of inspecting row lines 401, 402, 403 of the panel 40 is given. As shown in FIGS. 4 and 5, the signal inputting sensors 421, 422, 423 are configured in a first detecting bar 42, and the signal detecting sensors 431, 432, 433 are configured in a second detecting bar 43. In this embodiment, the panel 40 can be a raw TFT-array substrate. However, in other embodiments, the panel 40 can be a sliced TFT-array substrate.

In addition, each signal inputting sensor 421, 422, 423 can be aligned to one end of each conducting line 401, 402, 403 of the panel 40, and each signal detecting sensor 431, 432, 433 can be aligned to the other end of each conducting line 401, 402, 403 of the panel 40. The signal inputting sensor 421 and the signal detecting sensor 431 form a detecting unit such that a detecting signal provided by the signal inputting sensor 421 can be received by the signal detecting sensor 431. Similarly, the signal inputting sensor 422 and the signal detecting sensor 432 form a detecting unit, and the signal inputting sensor 423 and the signal detecting sensor 433 form a detecting unit. Thus, the signal inputting sensors 421-423 of the first detecting bar 42 and the signal detecting sensors 431-433 of the second detecting bar 43 form the detecting units.

In detection, the control circuit 41 can control a detecting unit at one time in order to detect a conducting line 401, 402 or 403 relative to the detecting unit on the panel 40. For example, the control circuit 41 controls the signal inputting sensor 421 to provide a voltage to the conducting line 401 for producing induced charges, and thus the signal detecting sensor 431, which belongs to a detecting unit the same as the signal inputting sensor 421, can receive the induced charges to accordingly determine if the conducting line 401 is open or short-circuited.

Next, the control circuit 41 controls the signal inputting sensor 422 to provide a detecting signal so that the signal detecting sensor 432 can detect induced charges produced by the conducting line 402. As cited, the control circuit 41 can control the signal inputting sensors 421, 422, 423 sequentially to provide the detecting signal and control the respective signal detecting sensors 431, 432, 433 to receive the detecting signal synchronously. Thus, inspecting the conducting lines 401-403 on the panel 40 in an electronic scanning manner is achieved to relatively reduce the tact-time and the probability of scraping the panel 40.

The panel 40 can be sliced up into a plurality of small substrates. The first detecting bar 42 and the second detecting bar 43 of the non-contact inspecting device can inspect the small substrates on one side each time. Accordingly, after each inspection is complete, the first detecting bar 42 and the second detecting bar 43 are moved to other non-inspected small substrates. In this embodiment, the amount of moving the bars 42, 43 for the detection is only twice, so as to effectively increase the productivity. In addition, the positions of the sensors 421-423 and 431-433 can be changed to fit in with different-resolution substrates without preparing different non-contact inspecting devices, thereby saving the cost of providing panel inspecting equipment.

In other embodiments, in order to accelerate the tact-time, the control circuit 410 can control multiple detecting units to inspect corresponding ones of the conducting lines 401-403 at one time. For example, the control circuit 410 can first control the odd signal inputting sensors 421, 423 to provide a voltage to the respective conducting lines 401, 403 thereby producing induced charges, and controlling the respective signal detecting sensors 431, 433 to receive the induced charges synchronously for inspecting the conducting lines 401, 403, and then control the even signal inputting and detecting sensors 422, 432 for detecting the even conducting line 402, thereby relatively reducing the tact-time.

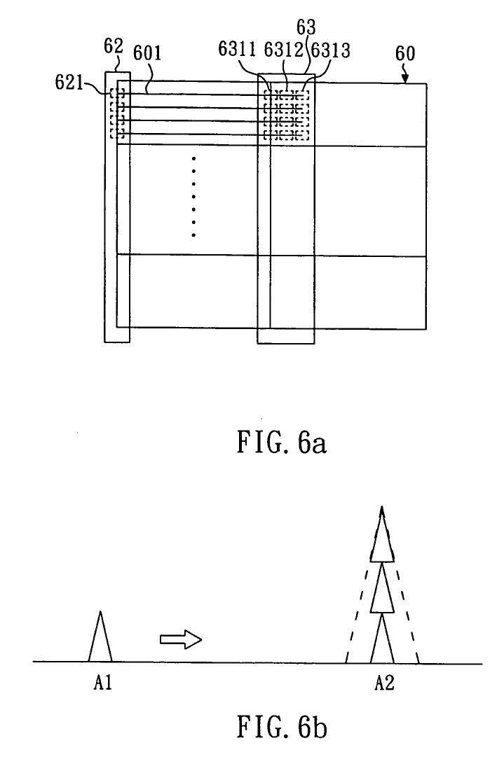

FIGS. 6a and 6b are schematic diagrams of a second embodiment of the invention. In FIG. 6a, a first detecting bar 62 includes a plurality of signal inputting sensors 621, and a second detecting bar 63 includes pluralities of signal detecting sensors 6311, 6312, 6313. In this embodiment, a signal inputting sensor 621 and a plurality of signal detecting sensors 6311, 6312, 6313 form a detecting unit.

Accordingly, when the signal inputting sensor 621 provides a voltage to a conducting line 601 on a panel 60, the conducting line 601 produces induced charges, and the signal detecting sensors 6311-6313 receives the induced charges. Thus, the accuracy of the inspection result is increased, and the intensity of the received signal is effectively increased by filtering out noise.

As shown in FIG. 6b, a difference is given by comparing the use of three signal detecting sensors with one. The notation Al indicates a waveform of a signal received by one signal detecting sensor, and the notation A2 indicates a waveform of the signal received by multi-signal detecting sensors. A waveform of a signal can be added by using multiple signal detecting sensors to concurrently receive the signal, which can increase the accuracy in a panel inspection. The high pass filter and low pass filter can be applied in signal process to reduce noise and enhance detecting intensity.

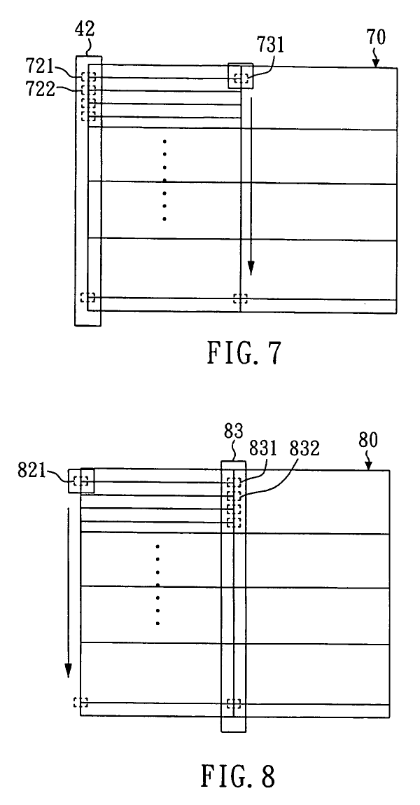

FIG. 7 is a schematic diagram of a third embodiment of the invention. In this embodiment, a first detecting bar 72 and a signal detecting sensor 731 are used to detect a panel 70. The first detecting bar 72 includes a plurality of signal inputting sensors 721, 722. Accordingly, the control circuit can control the signal inputting sensors 721, 722 on one end of conducting lines sequentially to provide a detecting signal and control the signal detecting sensor 731 to mechanically move to the other end of the respective conducting lines for receiving the detecting signal.

FIG. 8 is a schematic diagram of a fourth embodiment of the invention. In this embodiment, a signal inputting sensor 821 and a second detecting bar 83 are used to inspect a panel 80. The second detecting bar 83 includes a plurality of signal detecting sensors 831, 832. Accordingly, the control circuit can control the signal inputting sensor 821 to mechanically move for providing a detecting signal at the different positions and control the signal detecting sensors 831 and 832 sequentially to receive the detecting signal.

As cited, the invention uses the signal inputting sensors to form the first detecting bar and the signal detecting sensors to form the second detecting bar, such that the two detecting bars are used to inspect the panel directly. In addition, the control circuit can control the signal inputting sensors of the first detecting bar sequentially to provide a detecting signal and control the corresponding signal detecting sensors of the second detecting bar to receive the detecting signal synchronously. Thus, the panel is electronically scanned, the tact-time is reduced, and the panel productivity is effectively increased.

Although the present invention has been explained in relation to its preferred embodiment, it is to be understood that many other possible modifications and variations can be made without departing from the spirit and scope of the invention as hereinafter claimed.

What is claimed is:

1. A non-contact inspecting device for a panel applied to inspect the panel with a plurality of conducting lines, wherein the conducting lines comprises metal and its related alloy, transparent conductive oxide (TCO), or conductive organic polymer, the non-contact inspecting device comprising:
a first detecting bar, configured with a plurality of signal inputting sensors;
a second detecting bar, configured with a plurality of signal detecting sensors, wherein the signal inputting sensors and the signal detecting sensors are combined to form a plurality of detecting units; and
a control circuit, electrically connected to the signal inputting sensors and the signal detecting sensors respectively,
wherein each of the detecting units corresponds to a conducting line of the panel such that the control circuit controls the detecting unit to detect the conducting line.

2. The non-contact inspecting device as claimed in claim 1, wherein the control circuit controls one signal inputting sensor of at least one of the detecting units to provide a detecting signal, and the control circuit controls one signal detecting sensor of at least one of the detecting units to detect the detecting signal synchronously.

3. The non-contact inspecting device as claimed in claim 1, wherein the control circuit controls one signal inputting sensor of at least one of the detecting units to provide a voltage such that the conducting line produces induced charges, and the control circuit controls one signal detecting sensor of at least one of the detecting units to detect the conducting line by receiving the induced charges.

4. The non-contact inspecting device as claimed in claim 1, wherein the control circuit controls the detecting units to detect the conducting lines sequentially.

5. The non-contact inspecting device as claimed in claim 1, wherein each of the detecting units comprises one signal inputting sensor and one signal detecting sensor.

6. The non-contact inspecting device as claimed in claim 1, wherein each of the detecting units comprises one signal inputting sensor and a plurality of signal detecting sensors.

7. The non-contact inspecting device as claimed in claim 1, wherein the panel is a raw thin-film transistor array substrate or passive matrix substrate.

8. The non-contact inspecting device as claimed in claim 1, wherein the panel is a sliced thin-film transistor array substrate or passive matrix substrate.

9. A non-contact inspecting device for a panel applied to inspect the panel with a plurality of conducting lines, wherein the conducting lines comprises metal and its related alloy, transparent conductive oxide (TCO), or conductive organic polymer, the non-contact inspecting device comprising:
a first detecting bar, configured with a plurality of signal inputting sensors;
a signal detecting sensor, combining one of the signal inputting sensors into a detecting unit; and
a control circuit, electrically connected to the signal inputting sensors and the signal detecting sensor respectively,
wherein the detecting unit corresponds to a conducting line such that the control circuit controls the detecting unit to detect the conducting line of the panel, and for a subsequent conducting line of the panel to be detected by the detecting unit, the signal detecting sensor is moved to align and detect the subsequent conducting line.

10. The non-contact inspecting device as claimed in claim 9, wherein the control circuit controls one signal inputting sensor of the detecting unit to provide a detecting signal, and the control circuit controls the signal detecting sensor of the detecting unit to detect the detecting signal synchronously.

11. The non-contact inspecting device as claimed in claim 9, wherein the control circuit controls one signal inputting sensor of the detecting unit to provide a voltage such that the conducting line produces induced charges, and the control circuit controls the signal detecting sensor of the detecting unit to detect the conducting line by receiving the induced charges.

12. The non-contact inspecting device as claimed in claim 9, wherein the control circuit sequentially controls the signal inputting sensors to respectively provide a plurality of detecting signals, and the control circuit controls the signal detecting sensor to correspondingly move for detecting the detecting signals synchronously.

13. A non-contact inspecting device for a panel applied to detect the panel with a plurality of conducting lines, the non-contact detecting device comprising:
a signal inputting sensor;
a second detecting bar, configured with a plurality of signal detecting sensors, the signal inputting sensor and one or more signal detecting sensors forming a detecting unit; and
a control circuit, electrically connected to the signal inputting sensor and the signal detecting sensors respectively,
wherein the detecting unit corresponds to a conducting line such that the control circuit controls the detecting unit to detect the conducting line of the panel, and for a subsequent conducting line of the panel to be detected by the detecting unit, the signal inputting sensor is moved to cooperate with one or more signal detecting sensors for aligning and detecting the subsequent conducting line.

14. The non-contact inspecting device as claimed in claim 13, wherein the control circuit controls the signal inputting sensor of the detecting unit to provide a detecting signal, and the control circuit controls at least one of the signal detecting sensors of the detecting unit to detect the detecting signal synchronously.

15. The non-contact inspecting device as claimed in claim 13, wherein the control circuit controls the signal inputting sensor of the detecting unit to provide a voltage such that the conducting line produces induced charges, and the control circuit controls at least one of the signal detecting sensors of the detecting unit to detect the conducting line by receiving the induced charges.

16. The non-contact inspecting device as claimed in claim 13, wherein the control circuit sequentially moves the signal inputting sensor to align the conducting lines and provide a detecting signal, and the control circuit controls at least one of the signal detecting sensors to sequentially detect the detecting signal synchronously.

17. The non-contact inspecting device as claimed in claim 13, wherein the detecting unit comprises one signal inputting sensor and one signal detecting sensor.

18. The non-contact inspecting device as claimed in claim 13, wherein the detecting unit comprises one signal inputting sensor and a plurality of the signal detecting sensors.

19. The non-contact inspecting device as claimed in claim 13, wherein the panel is a raw thin-film transistor array substrate or passive matrix substrate.

20. The non-contact inspecting device as claimed in claim 13, wherein the panel is a sliced thin-film transistor array substrate or passive matrix substrate.
